(19) United States
(12) Patent Application Publication
(10) Pub. No.: US 2026/0319344 A1
(43) Pub. Date: Oct. 15, 2026

(54) ADJUSTABLE CONTENT CREATION SYSTEM

(71) Applicant: New Revolution Tools, LLC, Dubuque, IA (US)

(72) Inventors: Tony WAGNER, Zwingle, IA (US); Kevin KOCH, Farley, IA (US)

(73) Assignee: New Revolution Tools, LLC, Dubuque, IA (US)

(21) Appl. No.: 19/646,538

(22) Filed: Apr. 13, 2026

Related U.S. Application Data
(60) Provisional application No. 63/787,613, filed on Apr. 11, 2025.

(51) Int. Cl. G03B 17/56; H05K 5/02

(52) U.S. Cl. CPC G03B 17/561; H05K 5/0234

(57) ABSTRACT

An adjustable content creation system comprises a first support section having at least one first foot, a camera mount supported by the first support section, anda second support section having at least one second foot. The second support section is movably coupled to the first section for horizontal movement between a compact state and an extended state.

### CROSS-REFERENCE TO RELATED PATENT APPLICATIONS

The present application claims the benefit from co-pending US Patent Provisional Application Serial No. 63/787,613 filed on Apr. 11. 2025 by Wagner et al. and entitled ADJUSTABLE CONTENT CREATION SYSTEM, the full disclosure of which is hereby incorporated by reference.

### BACKGROUND

In the field of digital content creation and presentation, users often require a combination of one or more cameras, monitors, and tables. Traditionally, if a user has a camera mounted on a separate tripod, changing positions such as from a seated to a standing position or adjusting the height of a table requires independent adjustment of both a table and the tripod. This traditional setup and separate adjustments presents several technical challenges related to imprecision and time. Manually repositioning a tripod to match a new desk height is often time-consuming and imprecise. Presentation systems which utilize a translucent or transparent panel such as a lightboard bring an additional level of precision required to set and maintain alignment of the camera with that translucent or transparent panel.

Video recording systems often require significant effort, time, and cost to deploy from the manufacturer(s) to the customer during the initial setup phase. Utilizing multiple separate items for a presentation can create undesirable clutter in the workspace. For high-quality video, it is often ideal to place the camera at a specific distance away from the user to enable a specific field of view. If this required distance is larger than common pedestrian doorway openings, for example 36 inches, the system becomes difficult to transport in a single piece between rooms or locations.

### BRIEF DESCRIPTION OF THE DRAWINGS

FIG. 1 is a top perspective view illustrating an example adjustable content creation system in an operable, open state with a standing user.

FIG. 2 is a top perspective view of the adjustable content creation system of FIG. 1 in an open state, with a seated user, shown from a different angle.

FIG. 3 is a top perspective view of the adjustable content creation system of FIG. 1 in a folded closed state to require less space.

FIG. 4 is a top perspective view of an example adjustable content creation system in an open state.

FIG. 5 is a bottom perspective view of the adjustable content creation system of FIG. 4 in a folded closed state .

FIG. 6 is a top perspective view of the adjustable content creation system of FIG. 5 in a partially folded state.

FIG. 7 is a top view of a folding linkage of the adjustable content creation system of FIG. 6 in the partially folded state.

FIG. 8 is a top view of the folding linkage of FIG. 7 in a state typical of an open state.

FIG. 9 is a top perspective view of an example adjustable content creation system in an open state.

FIG. 10 is a bottom perspective view of the adjustable content creation system of FIG. 9.

FIG. 11 is a top perspective view of the adjustable content creation system of FIG. 9 in a folded closed state.

FIG. 12 is a top view schematically illustrating an example adjustable content creation system in an open state .

FIG. 13 is a top view schematically illustrating the adjustable content creation system of FIG. 11 in the folded closed state .

FIG. 14 is a top view schematically illustrating an example adjustable content creation system in a closed state.

FIG. 15 is a top view schematically illustrating the adjustable content creation system of FIG. 14 in an open state.

FIG. 16 is a top view schematically illustrating an adjustable content creation system in a first open state.

FIG. 17 is a top view schematically illustrating the adjustable content creation system of FIG. 16 in a second open state.

FIG. 18 is a top perspective view of an example adjustable content creation system in an open state.

Throughout the drawings, identical reference numbers designate similar, but not necessarily identical, elements. The figures are not necessarily to scale, and the size of some parts may be exaggerated to more clearly illustrate the example shown. Moreover, the drawings provide examples and/or implementations consistent with the description; however, the description is not limited to the examples and/or implementations provided in the drawings.

### DETAILED DESCRIPTION OF EXAMPLES

Disclosed are example adjustable content creation systems that facilitate the production of audio-video content. The example systems are designed to provide a unified, height-adjustable environment that can transform between a closed, compact state for transport or storage and an extended or open state for use. The adjustable content creation systems comprise a frame or support unit that comprises a first support section and a second support section. The first support section is configured to support or may support a camera. In some implementations, the second support section is configured to or may support a translucent or transparent screen. In some implementations, the second support section is configured to or may support other components or may provide a work surface. The first and second support sections are operably coupled to one another for relative movement between a compact state and an open, expanded or extended use state. In the extended use state, the camera is positioned to provide a predetermined or predefined field-of-view.

In some implementations, the compact state is a state where the first and second support sections are in close proximity to one another such that the farthest most opposite extremities or edges of the first and second support sections are spaced apart from one another by less than or equal to 36 inches, facilitating passage through a standard pedestrian doorway opening. In other words, the maximum dimension of the first and second support sections, when in the compact state is less than or equal to 36 inches. In the open or extended use state, at least portions of the first and second support sections are spaced apart by a distance greater than 36 inches or by distance such that the camera and the translucent or transparent screen are spaced apart from one another by a distance greater than 36 inches. In yet other implementations, the compact state and the open or extended use state may have other spacings or distances where the compact state corresponds to a spacing between the first and second support sections that is less than that of the system when the first and second support sections are in the open or extended use state. For example, in some implementations, the opposite outer portions of the first and second support sections may be spaced greater than 36 inches when in the compact state for passage through wider doorway openings or for reducing the volume occupied by the system when stored or transported.

In some implementations, the open or extended use state is preestablished or predefined as the maximum distance at which the first and second support sections may be separated or spaced from one another while remaining connected to one another as a single unit. In some implementations, the open or extended use state is a state where the first and second support sections are spaced from one another by a distance greater than 36 inches, or a distance such that the camera and the translucent or transparent screen are spaced apart from one another by a distance greater than 36 inches. The maximum distance that the first and second support sections may be moved away from one another and spaced apart from one another in the extended use state is established by construction, architecture or configuration of the frame or support unit. Said another way, the first and second support sections operably coupled to one another such that the maximum extent to which the first and second support sections may be pulled apart from one another, pivoted away from one another or otherwise separated (while remaining connected or coupled to one another) is limited by a mechanical or physical stop or endpoint. This maximum distance corresponds to a preestablished spacing between the camera and the translucent or transparent screen to provide the predetermined or preestablished field-of-view. As result, the recommended spacing between the camera and the translucent or transparent screen is easily achieved by the user simply moving the two support sections away from one another to the maximum separation distance of the two support sections. The user does not to need to tediously measure and tediously iterate between different spacings in an attempt to find the appropriate spacing that achieves the recommended field-of-view.

In some implementations, the first and second support sections are movable away from one another (pivoting, telescopic action or the like) to provide any of a number of user selectable spacings between the first and second support sections and/or the camera and the translucent or transparent screen. For example, in some implementations, the first and second support sections may be movable to provide a user selected spacing that may vary along a continuum of potential spacings between the support sections. In some implementations, the system may include a plurality of spaced markings that indicate different potential spacings available for the user to select. Such markings may indicate distance measurements, fields of view, camera settings and the like that correspond to different user selectable spacings between the support sections. In some implementations, the first and second support sections may be separated by distance that is greater than the spacing that corresponds to the recommended field-of-view, but wherein an arrow, mark or other indicator identifies particular relative positions of the first and second support sections along the spacing continuum that achieves the recommended field-of-view.

The first and second support sections may be extendable or expandable while being connected to one another using a variety of different mechanisms. In some implementations, the first and second support sections may be pivotably coupled or connected to one another at adjacent ends, wherein the opposite ends, supporting the camera and the translucent or transparent screen, are spread apart in response to pivoting of the first and second support sections. In such implementations, the opposite ends of the first and second support sections are linked or connected to one another by an intermediate link that operably connects the free ends, the opposite ends of the first and second support sections. This intermediate link may control the spacing between the free ends of the first and second support sections which correspond to the spacing between the camera and the translucent or transparent screen. In some implementations, this link may be collapsible, telescopic or foldable to facilitate pivoting of the free ends into an adjacent or near adjacent relationship. In some implementations, the link may also have a maximum extended length which corresponds to the maximum spacing that may be achieved between the first and second support sections. As noted above, this maximum spacing may also correspond to a predetermined art predefined spacing between the first and second support sections that also corresponds to a recommended field-of-view for the camera with respect to the translucent or transparent screen and its environment.

When the first and second sections are separated, the system is held in an open "V" arrangement. This configuration creates a desirable distance between the camera (mounted on the rear section) and the user or translucent panel (on the front section), allowing for a larger plane of view. When the first and second sections are pivoted about the main hinge until they are parallel, the overall system becomes significantly more narrow to allow for easy transport through standard pedestrian doorways.

In some implementations, this link may be in the form of one or more linkage arms hinged or pivotally connected to one another to enable the arms to be folded relative to one another (for the mobile compact state) or unfolded and extended (for the open extended in use state). In some implementations, this link may be in the form of a flexible cable, chain, rope or the like. In some implementations, this link may be provided in the form of a series of telescopic tubes having ends which are pivotally connected to the free ends of the first and second sections and which nest within one another (for the mobile compact state) or which telescope and extend (for the open extended use state).

In some implementations, the first and second support sections may be operably coupled to one another or movement between the compact state and the open or extended use state by two or more spaced apart telescopic connections between the first and second support sections. In such implementations, telescopic tubes may be provided such that the first and second support sections (as well as the supported camera and translucent or transparent screen) may be pushed together (nesting the telescopic tubes) for the compact state and made the pulled apart (un-nesting the tubes) for the open extended use state. For example, in some implementations, first adjacent end portions of the first and second support sections may be connected by a telescopic member or tube extending between the two first adjacent end portions while the second adjacent end portions of the first and second support sections are connected by a second telescopic member or tube extending between the two second adjacent end portions.

In some implementations, a powered actuator may be provided to move the first and second support sections between the compact state and the open extended in use state. Such actuators may be in the form of hydraulic or pneumatic cylinders, electric solenoid, or electric motors with appropriate gears (worm gear, rack and pinion gear or the like) to facilitate movement of the first and second members by either extending or retracting telescopic members or by pivoting the first and second support sections towards or away from one another.

In some implementations, the entire apparatus may be vertically supported by a plurality of telescoping legs, which may be electrically, hydraulically, or pneumatically actuated. Because the system operates as a single unit, the camera, monitors, tabletops, and translucent panel travel up and down simultaneously. This synchronized movement maintains precise alignment between the camera and the presentation surface throughout a wide adjustment range, accommodating both seated and standing users without requiring independent recalibration of equipment.

The system may include a translucent panel positioned between the user and the camera, which can serve as a physical writing surface for markers or a touch-interactive digital display. Alternate implementations include a plurality of center table sections and front extension tables that add horizontal workspace when deployed but fold away to maintain a small footprint for storage or transport. The system may incorporate a precision alignment system, utilizing lead screw or ball screw mechanisms to allow a user to precisely calibrate the camera's rotational angles and field of view relative to the translucent panel.

Disclosed systems provide complete, integrated solutions that reduces the effort, time, and clutter often associated with high-quality audio-video production and live-streaming. The example adjustable content creation systems provide a unified system that maintains precise alignment between cameras, monitors, and work surfaces while providing a mechanism to rapidly transform into a narrower profile for transport through standard pedestrian doorways.

For purposes of this disclosure, the term “coupled” shall mean the joining of two members directly or indirectly to one another. Such joining may be stationary in nature or movable in nature. Such joining may be achieved with the two members or the two members and any additional intermediate members being integrally formed as a single unitary body with one another or with the two members or the two members and any additional intermediate member being attached to one another. Such joining may be permanent in nature or alternatively may be removable or releasable in nature. The term “operably coupled” shall mean that two members are directly or indirectly joined such that motion may be transmitted from one member to the other member directly or via intermediate members.

For purposes of this disclosure, the phrase “configured to” denotes an actual state of configuration that fundamentally ties the stated function/use to the physical characteristics of the feature preceding the phrase “configured to”.

For purposes of this disclosure, the term “releasably” or “removably” with respect to an attachment or coupling of two structures means that the two structures may be repeatedly connected and disconnected to and from one another without material damage to either of the two structures or their functioning.

For purposes of this disclosure, the terms “fixedly” or “permanently” means that two pieces are connected such that they cannot be separated without damaging the connection between the two pieces such that they cannot be readily reconnected without additional glues, bonds, adhesives or pieces.

### DRAWING REFERENCE NUMERALS LIST

system 10

user 20

camera 22

first monitor 24

second monitor 26

translucent panel 28

front tabletop 30

rear tabletop 32

plurality of telescoping legs 34

telescoping leg inner section 35

plurality of wheels 36

telescoping leg outer section 37

front section 38

telescoping leg top 39

rear section 40

feet 41

pole 42

hinged feet 43

folding linkage 44

front linkage arm 46

rear linkage arm 48

main hinge pin 50

pin 51

front linkage hinge pin 52

center linkage hinge pin 54

rear linkage hinge pin 56

center linkage hinge bracket 58

hinge mounting holes 60

latch 62

system 110

system 210

plurality of center table sections 212

front extension table section 214

side hinges 216

center hinges 218

plurality of front hinges 220

front support arms 222

front support arm axles 224

motion controller 226

motion switch 228

mark 470

indicator 472

controller 476

motion switch wire 230

leg control wires 232

pole rotation hub 234

pin 236

system 310

pin joint 314

pin joint 316

pin joint 318

front section 338

rear section 340

link 342

link 344

pin joint 350

system 410

extendable linkage 412

front section 438

rear section 440

system 510

front section 538

rear section 540

bracket 542

bracket 544

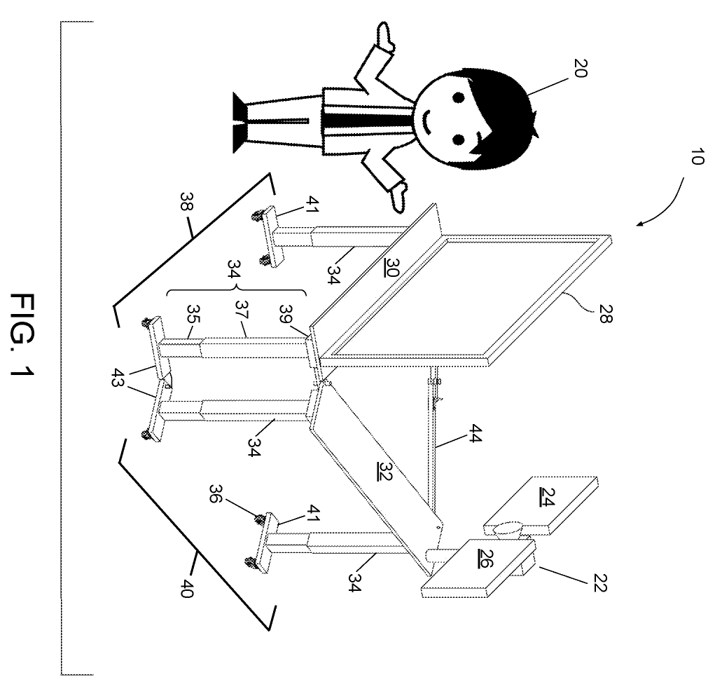

FIG. 1 is an isometric view of an example adjustable content creation system 10. User 20 stands in front of translucent panel 28 which may be partially translucent or transparent so camera 22 can see the image of user 20 through translucent panel 28. Translucent panel 28 may be written on with markers in order to present concepts, or translucent panel 28 may comprise a touch interactive digital display. A camera 22 sits between a first monitor 24 and a second monitor 26, where these monitors may display helpful information to user 20. Examples of camera 22 and translucent panel 28 are shown and described in co-pending US Patent Application Serial No. 19/204,874 filed on May 12, 2025 by Koch et al., the full disclosure which is hereby incorporated by reference. As should be appreciated, system 10 and each of the other systems described below may likewise comprise a camera and translucent panel/screen similar to those described in co-pending US Patent Application Serial No. 19/204,874. System 10 and each of the other systems may likewise comprise the additional system components described in co-pending US Patent Application Serial No. 19/204,874.

System 10 comprises a plurality of telescoping legs 34, a plurality of wheels 36, a front support section 38 and a rear support section 40. Front section 38 comprises translucent panel 28, front tabletop 30, and a plurality of telescoping legs 34. Rear section 40 comprises a rear tabletop 32, first and second monitors 24 and 26, camera 22, a plurality of telescoping legs 34. Within each of the plurality of telescoping legs 34 there are 3 major sections including telescoping leg top 39, telescoping leg outer section 37 and telescoping leg inner section 35.

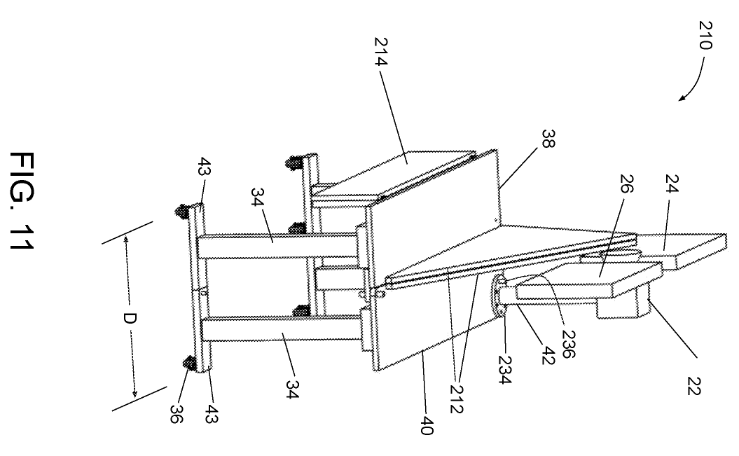

As a helpful feature, user 20 can adjust the height of system 10 easily by actuating the plurality of telescoping legs 34 which may be electrically, hydraulically, or pneumatically actuated. When the height of system 10 is adjusted, each telescoping leg inner section 35 will traverse into or out of the adjacent telescoping leg outer section 37 to retract its length or extend its length. Preferably the plurality of telescoping legs 34 will be electrically actuated by a single height controller to coordinate the length of all being kept in unison at all times including while extending or shortening, thus raising or lowering system 10. The height controller (later depicted in FIG. 10) may achieve this consistent motion throughout the plurality of telescoping legs 34 by means of a position feedback system and variable power output to drive electric motors. Electric motors may turn a threaded rod which extends the telescoping assembly in a variety of ways that are known to industry. Other linear actuator mechanisms and technologies including hydraulic and pneumatic actuates are contemplated herein. In that way, user 20 need only press a button for the system to quietly raise or lower to accommodate their preferred position whether they are seated or standing, based on their height and preferred positioning. System 10 is connected and operated as a single unit, so camera 22 and monitors 24 and 26 also travel up and down with translucent panel 28. In various instances, it is ideal to maintain alignment between camera 22 and translucent panel 28, which this system allows to be retained simply, even throughout a wide adjustment range. The height controller may optionally contain multiple position settings saved in memory to allow for quick adjustment to pre-defined positions for various users.

Some of the plurality of telescoping legs 34 are attached to feet 41, while others are attached to a hinged feet 43 on the opposite side of system 10. Hinged feet 43 comprise two similar bodies which pivot in relative motion to each other which will be more evident in subsequent figures.

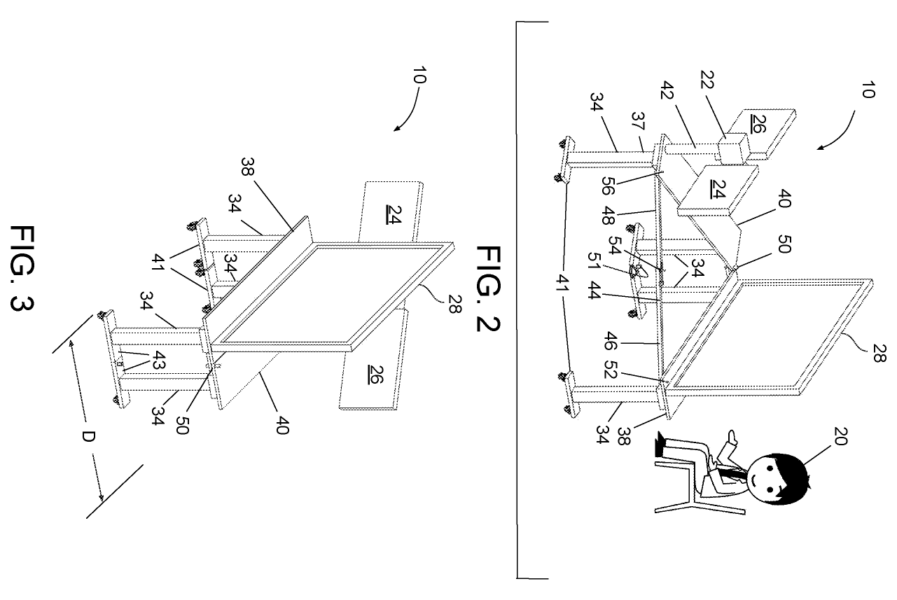

FIG. 2 is an isometric view of system 10 in an open “V” arrangement. This is the same arrangement as FIG. 1 after lowering system 10 to a lower setting to accommodate the same user 20 which is now seated on a chair. System 10 is being viewed from a different angle. While the plurality of telescoping leg outer sections 37 are shown, the plurality of telescoping leg inner sections 35 from FIG. 1 are not visible as they have telescoped fully inside of the plurality of telescoping leg outer sections 37. Pole 42 is shown which holds camera 22, monitor 24 and monitor 26 to rear section 40. Main hinge pin 50 connects front section 38 and rear section 40 in a pivotable arrangement. Folding linkage 44 connects the opposite side of front section 38 and rear section 40. Folding linkage 44 is comprised of a front linkage arm 46 and a rear linkage arm 48 which are joined together by center linkage hinge pin 54. Front linkage arm 46 is further connected to front section 38 by front linkage hinge pin 52 and rear linkage arm 48 is connected to rear section 40 by rear linkage hinge pin 56. When front linkage arm 46 and rear linkage arm 48 are arranged mostly end to end, they will hold system 10 open in a “V” shaped arrangement where the camera 22 is a distance away from front section 38, as shown. Note the distance between feet 41

FIG. 3 is an isometric view of system 10 in a folded closed arrangement to take up less space than the open “V” arrangement shown in FIGS. 1 and 2. In the present figure, front section 38 is parallel to rear section 40 after having been pivoted about main hinge pin 50 from the state depicted in FIGS. 1 and 2. Note that feet 41 are now much closer together after the system was folded closed. Also, hinged feet 43 have been rotated so the two bodies are in parallel alignment from the folding closed motion. Hinged feet 43 pivot about pin 51 which is coaxial to main hinge pin 50. .

In some implementations, the opposite outermost extremities of system 10 (corresponding to the outermost edges of sections 38 and 40 as defined by the outer edges of tabletop 30, 32 and/or feet 43 ) are separated by a distance D that is no greater than 36 inches when system 10 is in the compact state shown in FIG. 3, facilitating passage through a standard doorway. In other words, system 10 has a maximum dimension in at least one orthogonal horizontal direction that is no greater than 36 inches. In the example illustrated, the distance D (the maximum horizontal dimension of system 10 in at least one orthogonal direction) is measured along a horizontal axis perpendicular to the face of screen 28 or perpendicular to the longitudinal axis (the longest length or dimension) of sections 38, 40.

Conversely, when system 10 is in the extended state, at least portions of such outermost extremities of system 10 are spaced by a distance greater than 36 inches and camera 22 and screen 28 are likewise spaced by distance greater than 36 inches. In other implementations, system 10 may have a maximum dimension in at least one orthogonal horizontal direction that is greater than 36 inches for when larger entrances or doorways are provided. Even in such implementations, system 10, in the compact state, is more mobile and occupies less space when being stored or not being used.

Unlike traditional content creation systems that utilize a linear slide or a cantilevered arm to achieve the necessary focal distance between the camera and the user, particular example systems utilize a pivoting frame assembly. An open 'V' arrangement or telescoping extension frame widens the physical footprint of the system and offers physical support near to the expanded extremities of the system which provides superior structural integrity. This greatly reduces overall deflection in the system compared to the mechanical deflection often associated with cantilevered beams or telescopic slides. This structure ensures that the camera 22 or other position-sensitive equipment remain well supported in a stable, vibration-resistant orientation relative to the front section 38 even while the system is being used or the entire unit is being raised or lowered. Specifically, this system having a wider physical footprint than a pedestrian doorway when it is in the expanded state gives the system substantially greater stability.

In contrast, common height adjustable desks can have substantial wobble in operation considering the flexibility of a single pair of legs. Even if additional legs are added for stability, the overall footprint of the desk on the floor would still limit the overall stability of the system when that footprint is fixed and must pass through a pedestrian doorway.

By increasing the overall stiffness of the structure, the present invention will significantly reduce overall deflection and also gain substantial benefits in terms of vibration resistance. The more rigid system of the present invention creates a higher natural frequency which can then be above the range of common floor vibrations or user interactions. This greatly reduces disconcerting and undesirable camera shake and movement.

With conventional systems that have a width greater than pedestrian doorway openings, for example, having a width greater than 36”, it would be very difficult to transport such a system between locations and between rooms. By allowing a system like this to quickly transform into a narrower profile, transportation through pedestrian doorways can be made substantially more simple. The disclosed systems further enable rapid deployment not only for between uses, but also for transportation and the initial set up phase. This may result in a substantial reduction of effort, frustration, time and cost.

The option of increased distance without sacrificing portability can also be of interest to put more things into the comfortable view of a user. For example, if a user is only comfortable pivoting their gaze side to side and up and down within a given angular range, given a maximum distance from them to the viewing plane, the amount of physical area they can view is limited to a specific area value. If the viewing plane can be moved for example twice as far away from the user, they will be able to comfortably view an area that is twice as wide and twice as tall as before. This may be useful for example to view an array of monitors of a given size, with a system offering a 2x expansion allowing the user to see four times the area.

While not explicitly shown, the system disclosed may include a precision camera alignment head which is commercially available. Such a precision camera alignment head would be located between pole 42 and camera 22. This will allow a technician a controlled means to precisely calibrate the position and rotational angles of the camera, for example to precisely image the translucent or transparent panel without missing any part of the translucent panel, or not image any perimeter framing around the translucent or transparent panel. Alternatively, a Pan-Tilt-Zoom camera may be employed to provide electronic adjustment of the camera viewing direction and zoom setting. A telescoping function in pole 42 may enable vertical adjustment and pole 42 may be mounted upon slots or an oversized hole to enable positional movement of the pole if desired.

Translucent panel 28 may comprise a variety of structures including a solid translucent sheet such as glass or acrylic, a lightboard made with a translucent sheet and also lights illuminating the sheet from the edges, a partially frosted translucent sheet to develop a projected image from a projector, a translucent sheet in conjunction with an applied film, surface finish, or embedded particles to develop a projected image from a projector, or a translucent or transparent digital display such as one comprising organic light emitting diode (OLED) or micro light emitting diode (LED) pixels. Any of these panels may also include touch sensors such as infrared light frames or touch layers based on capacitance or resistance, or gesture monitoring systems to allow users to interact with content and send that interaction signal to a computer.

In order to eliminate reflections of monitors off of translucent panel 28, when present, a polarizing filter may be installed on camera 22 and rotated to filter polarized light emitted by first monitor 24 and second monitor 26.

While not explicitly shown, a variety of computing equipment and audio and video collection and processing equipment may be mounted to either the front or rear sections, or both of the present invention, in order to streamline the deployment, use, and storage of such a system. A pre-wired internal wiring harness can be used to route power and signal cables within and between the sections 38 and 40 to allow the entire system to be powered by a single power cord.

The system may include sensors such as an radio frequency identification (RFID) reader to read an employee badge to adjust the height of the system to a user’s preferred height. The camera sensor alone or in combination with a video processor may utilize standard industry methods such as those used in facial-recognition-based autofocus to identify the height of the user’s face and adjust the height of the system to the ideal height to accommodate that given user.

### Operation

One possible benefit to the present invention is the ability to adjust the height of many items which classically would require separate adjustment. As an example, if a user was presenting while utilizing a traditional height adjustable desk and a camera mounted on a traditional tripod, if they were to move the desk from a seated position to a standing position, they would then also need to adjust the tripod to reposition the camera for a similar view of the now standing user. This may be both time-consuming and imprecise. Further, the placement of these separate items may create additional clutter which is undesirable.

As an illustrative example, a user may store such a system in the compact state generally depicted by FIG. 3, where the system is folded closed and lowered down as far as it can go. The user can retrieve such a unit from storage, roll it through a common pedestrian doorway such as 36 inches wide or narrower and then into an office, studio, or classroom. They can then expand the unit into the open “V” state as shown in FIGS. 1 and 2 by separating the front and rear sections and manipulating the folding linkage until it reaches a calibrated positive stop where the linkage members are largely parallel. Further, they may then adjust the height of the unit to their liking, whether they prefer to be seated or standing, and even to accommodate their height versus the height of other users who may be taller or shorter and thus prefer a higher or lower height adjustment setting. The structural stiffness of the V-shape expanded system can prevent significant camera bouncing, motion blur, or parallax drift during height transitions.

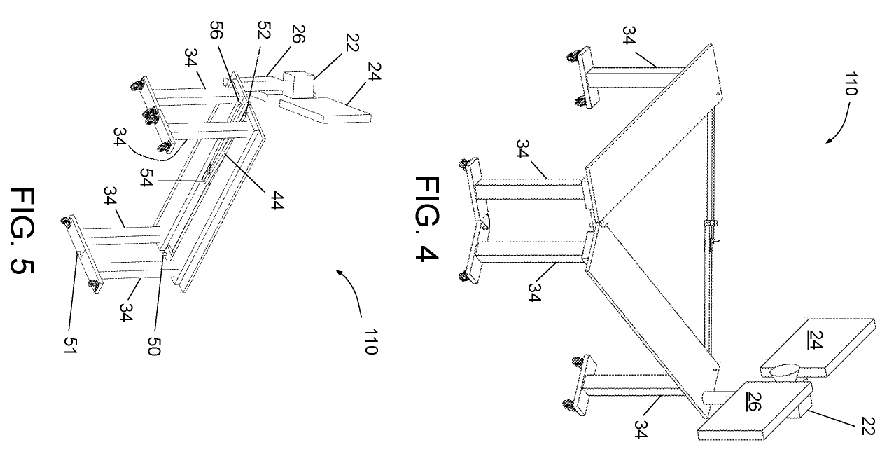

FIG. 4 is an isometric view of an alternate implementation of the present invention in which there is no translucent panel present as had been depicted in prior figures. System 110 may be utilized as an office desk, where the operation is otherwise similar to the prior implementation. The user may still enjoy the benefits of easy height adjustment of the entire system including the tabletops, camera, and monitors. They can also enjoy the quick deployment from a compacted state to a larger, more open state where the camera has a larger distance from the user for a more desirable view of the user and to allow a larger plane of view where the user is located. The monitor and camera positions may be optionally adjustable for accommodating this type of use, for example allowing the monitor stand to be rotated or traversed sideways to be closer to the center of the rear tabletop 32.

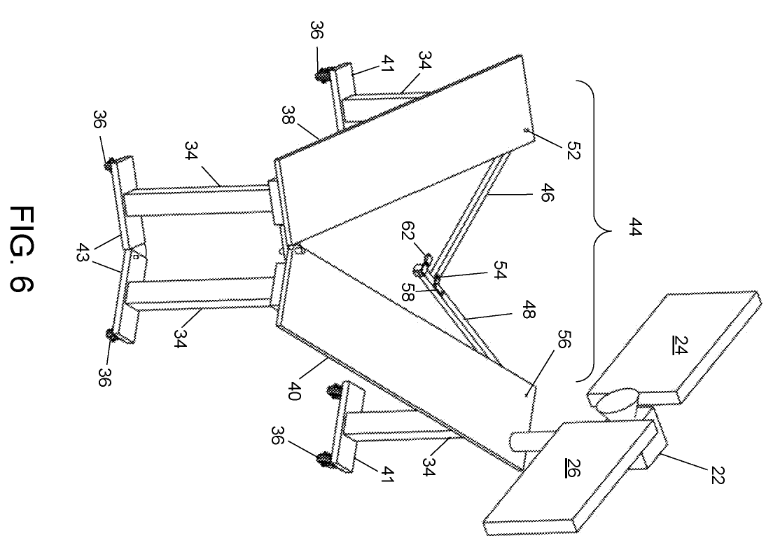

FIG. 5 is an isometric view of system 110 now looking from below, in order to show folding linkage 44 in a folded state. Also indicated are main hinge pin 50, front linkage hinge pin 52, center linkage hinge pin 54, and rear linkage hinge pin 56.

FIG. 6 depicts a second implementation in a partially folded state. Folding linkage 44 is depicted with front linkage arm 46 and rear linkage arm 48 at a relative angle to each other, no longer longitudinally parallel as they would be in the open configuration shown in FIG. 4 for example. It can be seen that front linkage arm 46 has pivoted about front linkage hinge pin 52 and rear linkage arm 48 has pivoted about rear linkage hinge pin 56. A center linkage hinge bracket 58 is connected to rear linkage arm 48 and provides a rotation point for center linkage hinge pin 54 thereby connecting front linkage arm 46 and rear linkage arm 48 in a rotatable pinned arrangement.

Latch 62 is shown attached to the free end of rear linkage arm 48, with latch 62 able to be fashioned in a variety of manners including as a simple cantilevered hook shape. When linkage 44 is transitioned to the open configuration, it can engage with front linkage arm 46 to temporarily lock folding linkage 44 and front linkage arm 46 in a longitudinally parallel fashion.

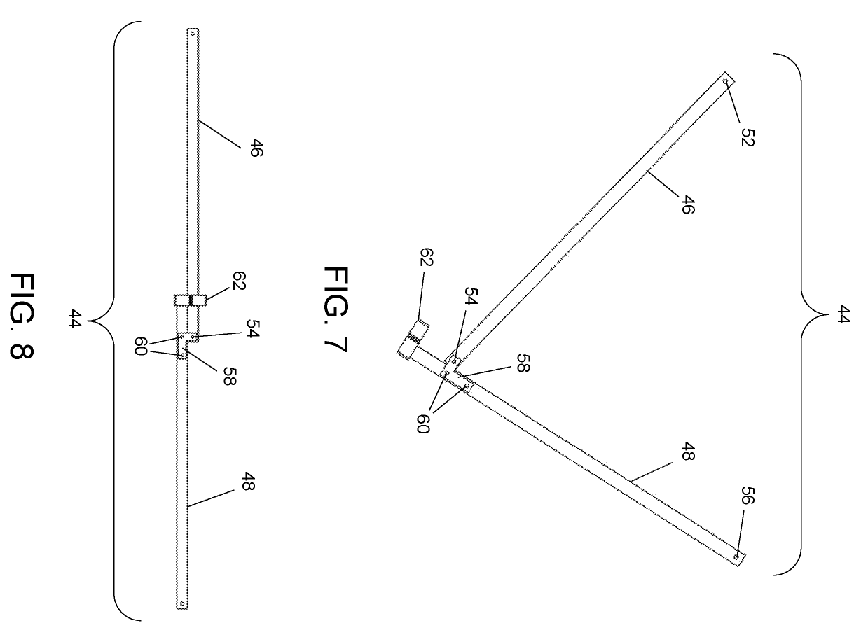

FIG. 7 again depicts the folding linkage 44 in the partially folded state shown in FIG. 6, now in a top-down view. Main hinge pin 50, front linkage hinge pin 52, and center linkage hinge pin 54 are all shown. Center linkage hinge bracket 58 contains hinge mounting holes 60 which fasten center linkage hinge bracket 58 to rear linkage arm 48. Rear linkage arm 48 may contain slots to allow hinge bracket 58 a range within which it can be fastened and adjusted. By adjusting the hinge bracket 58 position along rear linkage arm 48, the length of folding linkage 44 may be extended or shortened to adjust the relative position of front section 38 and rear section 40 depicted in earlier figures, when they are in the open arrangement.

FIG. 8 depicts the folding linkage 44 in the state typical of an open arrangement. Front linkage arm 46 and rear linkage arm 48 are now shown in a longitudinally parallel relationship and latch 62 has engaged front linkage arm 46. By adjusting the hinge bracket 58 position along rear linkage arm 48, the length of folding linkage 44 may be extended or shortened.

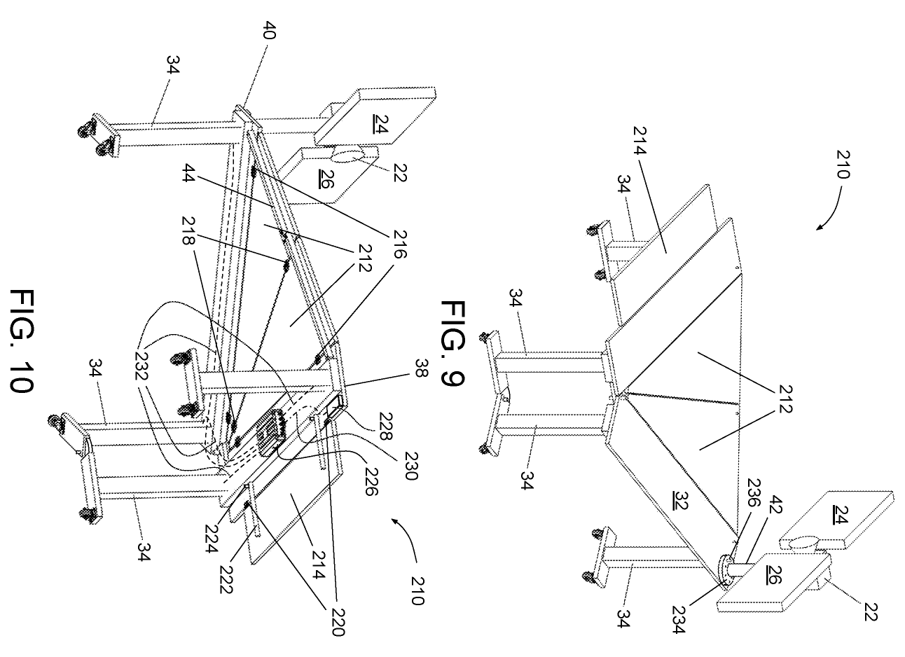

FIG. 9 is an isometric view of another alternate implementation in which there are movable tabletop sections. System 210 has a plurality of center table sections 212 which add usable horizontal work surfaces when deployed, yet when stored allow the overall footprint of the unit to be notably smaller for portability through standard pedestrian doorways, and transport and storage within a smaller footprint. Similarly, front extension table section 214 adds additional space. Pole 42 is now affixed to pole rotation hub 234 in a manner that allows rotation about the axis of pole 42 unless a pin 236 interfaces with aligned holes rear tabletop 32 and pole rotation hub 234 and thus pole 42 becomes rotationally fixed relative to rear tabletop 32.

FIG. 10 is an isometric view of system 210 now looking from below. Front extension table section 214 is attached to front section 38 via a plurality of front hinges 220. A plurality of front support arms 222 may be rotated into place to serve to support front extension table section 214 when it is used. Front support arms 222 rotate about front support arm axles 224 and a torsion spring may be used to bias the rotation of front support arms 222 towards a specific direction such as towards front extension table section 214 to speed the transition from a compact to an extended state. A plurality of side hinges 216 connect the plurality of center table sections 212 to front section 38 and rear section 40. Center table sections 212 may be further connected to each other with a plurality of center hinges 218. The weight of center table sections 212 may rest upon folding linkage 44. Further, an operator raising the plurality of center table sections 212 may be used as a means to deploy and retract system 210 between its two primary states of interest, the compact and extended states.

Motion controller 226 is connected to motion switch 228 via motion switch wire 230 depicted as a dash-dot line. A user may interface with motion switch 228 to raise and lower the entire system 210. Leg control wires 232 depicted as dashed lines connect a plurality of telescoping legs 34 to motion controller 226. Leg control wires 232 may transmit both power from motion controller 226 to the plurality of telescoping legs 34 and also a position feedback signal from the plurality of telescoping legs 34 to the motion controller 226 in order to coordinate smooth even motion within the plurality of telescoping legs 34 to ensure system 210 raises and lower smoothly and evenly to maintain the desired aliments previously discussed.

While not explicitly shown in FIG. 10, locking mechanisms such as latch 62 shown in earlier figures may hold the system in an open state. Similar or alternate locking methods may further hold the system in a folded closed state, for the sake of avoiding nuisance relative movement while moving the system in the folded closed state.

FIG. 11 depicts the third implementation in a folded closed state. As compared to FIG. 10, front extension table section 214 has been folded down and the plurality of center table sections 212 have been folded up while the front section 38 and rear section 40 were pivoted together about front linkage hinge pin 52 to arrive at the folded closed state shown. In order to fold the front extension table section 214 down, the plurality of front support arms depicted in FIG. 10 had to be rotated about front support arm axles 224. Further, it can be seen that pole 42 which holds camera 22, monitor 24 and monitor 26 to rear section 40 has been rotated such that monitor 24 and monitor 26 are substantially parallel to the longitudinal edge of rear section 40 to make the system more compact to pass through pedestrian doorways for example. Note, at the base of pole 42 is a hub 234 with multiple pin holes. These pin holes may be used to fix the rotational position of pole 42 in different positions including a typical operational position and a typical storage position by engaging different holes in hub 234 with a hole in rear tabletop 32.

As an illustrative example, the implementation shown in FIGS. 9, 10 and 11 may be configured into a folded state by raising the plurality of center table sections 212 while further pushing folding linkage 44 inward to fold that system into a more compact unit. Front extension table section 214 may be folded downward after moving the plurality of front support arms 222 inwards. In other implementations, lower surface of tabletop 30 may support a pair of spaced tracks along which section 214 is slidable such that table section 214 may be slid out from beneath tabletop 30 along such tracks to an extended or deployed state and may be slid along such tracks to beneath tabletop 30 to a retracted or undeployed state.

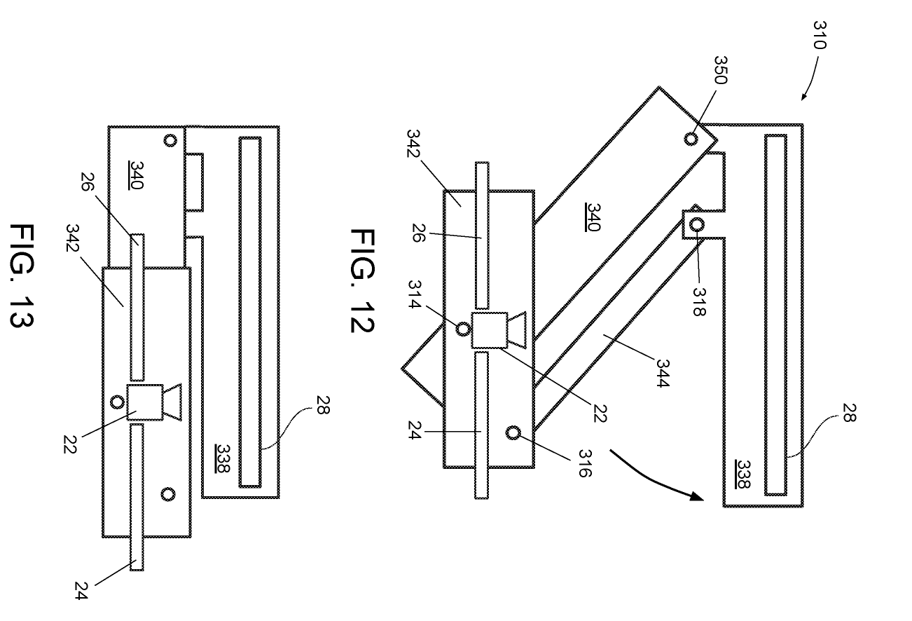

It is contemplated that a variety of mechanical systems may be used to mechanically link the rotation of pole 42 to the relative rotation of front section 38 and rear section 40 about main hinge pin 50. In some arrangements, first monitor 24 and second monitor 26 may be maintained with their longitudinal axis parallel to the longitudinal direction of front section 38. For example, in FIG. 12 depicts a fourth implementation, system 310 in an open arrangement in a top-down view where a four-bar linkage mechanism is employed. The four-bar linkage mechanism is comprised of front section 338, rear section 340, link 342, and link 344. These links are connected via pin joints 350, 314, 316, 318. Monitors 24 and 26 and camera 22 are mounted to link 342.

FIG. 13 depicts the fourth implementation now in the folded closed arrangement in a top down view. The system has been operated from the configuration shown in FIG. 12 where the 4-bar linkage arrangement has ensured link 342 has the desired angle relative to front section 338 in the open arrangement, but also is tightly packaged in the folded closed arrangement without requiring direct positioning other than pivoting rear section 340 relative to front section 338.

Alternatively, a sprocket and chain mechanism may achieve similar management of the orientations of a camera and monitors. For example, a sprocket centered about main hinge pin 50 or main hinge pin 350 and rotationally fixed relative to front sections 38 or 338 and a sprocket connected to a freely rotating pole such as pole 42 with a chain connecting both may achieve the desired motion when there is relative motion between front section 38 and rear section 40 or front section 338 and rear section 340.

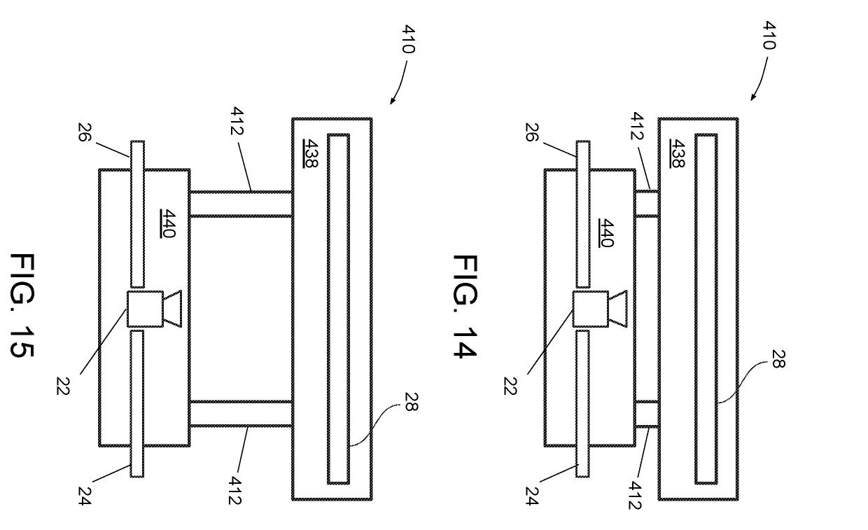

FIG. 14 depicts a fifth implementation in a compacted state. System 410 comprises front section 438 and rear section 440 which are connected by a plurality of extendable linkages 412. Extendable linkages 412 can extend or retract to achieve both a compacted state for efficient storage and transport as well as an extended state which achieves greater distance between a camera 22 and monitors 24 and 26.

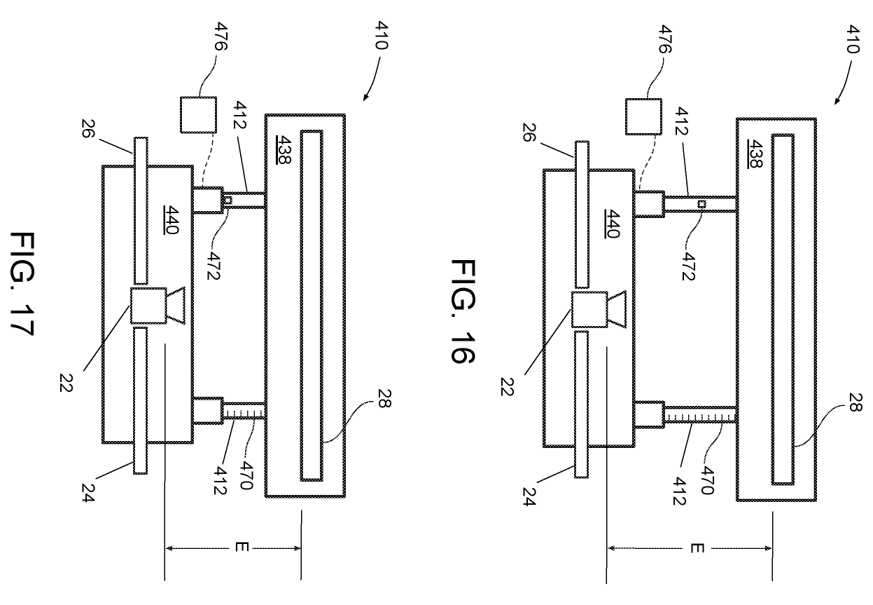

FIG. 15 depicts the fifth implementation in an extended state. As can be seen from comparing to FIG. 14, front section 438 and rear section 440 are now spaced at an increased distance due to extension of extendable linkages 412. Extendable linkages 412 may take a variety of forms including but not limited to telescoping tubes, hydraulic cylinders, pneumatic cylinders, linear electric actuators and scissor mechanisms. These connections may be passive to maintain position and stability only or they may be powered mechanisms. It is contemplated that having multiple extendable linkages spaced apart horizontally as well as spaced apart vertically can add stability to the entire system. For example, there may be two extendable linkages 412 connecting to frame members relatively near the floor and two extendable linkages 412 connecting to front section 438 and rear section 440 relatively near their top working surfaces. It is contemplated that one or more of the extendable linkages 412 may be removable in order to more easily allow users the ability to walk over or walk under the remaining system. For desired support, there would preferably be one or more support members in contact with the floor in both front section 438 and rear section 440. For example, two telescoping legs may support each of front section 438 and rear section 440. By having one or more legs supporting both sections, the deflection and vibration associated with cantilevered beams can be greatly reduced for more stable operation and less undesirable shake of any given section. While not shown, removable surfaces may be added in the gap between front section 438 and rear section 440 to increase the amount of horizontal surface area available.

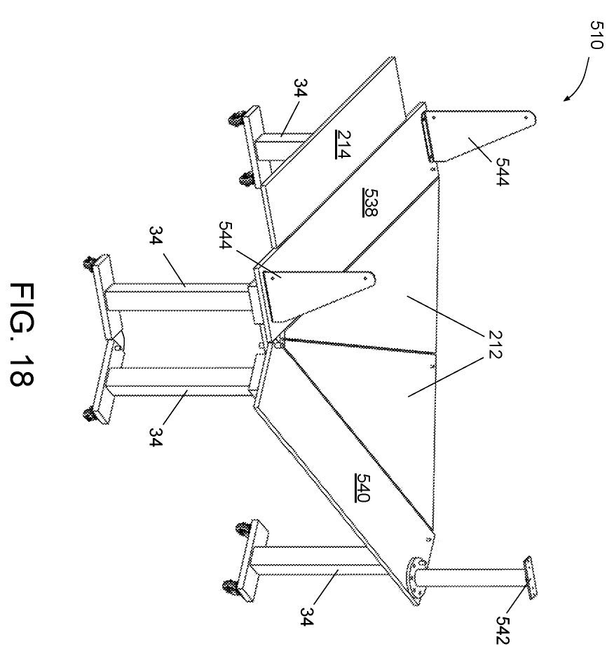

FIGS. 16 and 17 illustrate system an alternative implementation of system 410, wherein extendable links 412 comprise telescopic links and wherein configured to provide any of a number of user selectable spacings between the first and second support sections 438, 440 and/or the camera 22 and the translucent or transparent screen 28. In some implementations, such telescopic links 412 may comprise telescopic tubes or bars which are manually extendable and retractable in other implementations, such telescopic links 412 may comprise a hydraulic or pneumatic cylinder-piston assemblies or electric solenoid, also serving as a powered actuator for adjusting the spacing between sections 438 and 440. In such implementations, as indicated by broken lines, such powered actuators may be under the control of the controller 476 (schematically illustrated) which controls the length of links 412 to control the spacing between support sections 438 and 440. In some implementations, controller 476 may output electrical signals in the case of an electric solenoid or signals to a manifold and pump where links 412 comprise hydraulic or pneumatic cylinders.

In the illustrated example, the first and second support sections 438, 440 may be movable to provide a user selected spacing (distance E) that may vary along a continuum of potential spacings between the support sections 438, 440. In some implementations, the system for 10 may include a plurality of spaced markings 470 that indicate different potential spacings available for the user to select. Such markings 470 may indicate distance measurements, fields of view, camera settings and the like that correspond to different user selectable spacings between the support sections 438, 440. In some implementations, the first and second support sections 438, 440 may be separated by distance that is greater than the spacing that corresponds to the recommended field-of-view, but wherein an arrow, mark or other indicator 472 identifies particular relative positions of the first and second support sections along the spacing continuum that achieves the recommended field-of-view for camera 22.

FIG. 18 depicts a sixth implementation in an extended state. System 510 is similar to system 210 described above except that system 510 omits camera 22, and monitors 24, 26. System 510 comprises front section 538, rear section 540, front extension table 214 and plurality of center table sections 212. System 510 may be used for a variety of tasks including office work, meetings, dining, manufacturing and more, all while being capable of being folded into a more compact state for storage and transportation.

As further shown by FIG. 18, in some implementations, front section 538 and rear section 540 may include mounting provisions or brackets 542 and/or 544 for mounting one or more of a camera, a monitor, a computer keyboard, a piano-style keyboard, manufacturing equipment or other useful equipment or equipment provisions. Additional adornments may be added to make system 510 depict another structure such as a grand piano. System 510 may also be used as the legs and support structure for a grand piano.

The example systems as disclosed may be utilized for collection of photographic content, audio content, video content, live videoconference calls, office work, or any combination of these. Such content may be recorded to media for future use, or it may be live streamed to a variety of media platforms.

Although the claims of the present disclosure are generally directed to an adjustable content creation system having sections that are movable relative to one another to position a camera to establish a field-of-view, the present disclosure is additionally directed to the features set forth in the following definitions.

Definition 1: An apparatus for production of audio-video content comprising;

a frame with two connected, pivotable sections,

pivoting between a folded, mobile state, and an open extended use state,

a camera connected to said frame.

Definition 2: The apparatus for production of audio-video content of Definition 1 wherein there are one or more flat table surfaces.

Definition 3: The apparatus for production of audio-video content of Definition 1 wherein the frame is comprised of adjustable length legs.

Definition 4: The apparatus for production of audio-video content of Definition 1 wherein there is a translucent or transparent panel between a user and said camera.

Definition 5: The apparatus for production of audio-video content of Definition 1 wherein said translucent panel is comprised of glass and said user writes on it with an ink-filled marker.

Definition 6: The apparatus for production of audio-video content of Definition 1 wherein said translucent panel is comprised of a partially translucent or transparent digital display with a touch sensor and said user interacts with content by touching the panel.

Definition 7: The apparatus for production of audio-video content of Definition 1 wherein a hinged work surface is movably included between a first horizontal work surface and a second horizontal work surface.

Definition 8: The apparatus for production of audio-video content of Definition 1 wherein a database of user preferred settings are retained where adjustment to those settings can be triggered by facial recognition or physical access credentials.

Definition 9: A method of production of audio-video content comprising:
providing a frame having a first section and a second section pivotably connected to one another;
pivoting the first section relative to the second section between a folded, mobile state and an open extended use state;
and capturing images of a user with a camera connected to said frame.

Definition 10: The method of production of audio-video content of Definition 9, further comprising supporting objects upon one or more flat table surfaces attached to the frame.

Definition 11: The method of production of audio-video content of Definition 9, further comprising adjusting a height of the frame via a plurality of adjustable length legs.

Definition 12: The method of production of audio-video content of Definition 9, further comprising positioning a translucent panel between the user and the camera.

Definition 13: The method of production of audio-video content of Definition 12, further comprising recording writing applied to the translucent panel by the user with an ink-filled marker, wherein the translucent panel is comprised of glass.

Definition 14: The method of production of audio-video content of Definition 12, further comprising detecting user interaction with digital content via a touch sensor, wherein the translucent panel is comprised of a partially translucent or transparent digital display.

Definition 15: The method of production of audio-video content of Definition 10, further comprising deploying a hinged work surface into a position between a first horizontal work surface and a second horizontal work surface to expand a continuous horizontal workspace.

Definition 16: The method of production of audio-video content of Definition 9, further comprising retrieving user preferred settings from a database and triggering a height adjustment of the frame based on facial recognition or physical access credentials.

Definition 17: An adjustable content creation system comprising:
a first support section comprising at least one first foot and supporting a camera; and
a second support section comprising at least one second foot and supporting a translucent or transparent screen, the second support section being movably coupled to the first section for horizontal movement between a compact state and an extended state.

Definition 18: The system of Definition 17, wherein the first support section comprises a first table surface, wherein the second support section comprises a second table surface, and wherein edges of the first table surface and the second table surface are in abutment in response to the first support section and the second support section in the compact state.

Definition 19: The system of Definition 17 further comprising at least one monitor supported by the first support section.

Definition 20: The system of Definition 19, wherein the first support section has a first longitudinal axis, wherein the second support section has a second longitudinal axis, the first longitudinal axis and the second longitudinal axis extending parallel to one another when the first support section and the second support section are in the compact state and wherein the at least one monitor is pivotable between a first position in which the at least one monitor has a monitor face extending in first a plane parallel to the first longitudinal axis and a second position in which the monitor face extends in a second plane nonparallel to the first longitudinal axis.

Definition 21: The system of Definition 20, wherein the camera is pivotable between a first camera position facing in a direction perpendicular to the first longitudinal axis and a second camera position facing in a direction non-perpendicular to the first longitudinal axis.

Definition 22: The system of Definition 17, wherein the first support section comprises at least one vertical telescopic leg and wherein the second support section comprises at least one second vertical telescopic leg.

Definition 23: The system of Definition 22, further comprising at least one powered actuator operably coupled to at least one of the at least one first vertical telescopic leg and the at least one second vertical telescopic leg for raising and lowering the first support section and the second support section.

Definition 24: The system of Definition 23 further comprising a controller configured to output signals to the at least one powered actuator for raising and lowering the first support section and the second support section.

Definition 25: The system of Definition 17, wherein the first support section comprises a first longitudinal end portion and a second longitudinal end portion, wherein the second support section comprises a first longitudinal end portion and a second longitudinal end portion, wherein the first longitudinal end portion of the first support section is pivotably coupled to the first longitudinal end portion of the second support section, wherein the second longitudinal end portion of the first support section and the second longitudinal end portion of the second support section are free ends connected by a linkage extending therebetween.

Definition 26: The system of Definition 25, wherein the linkage is a folding linkage comprising a first arm pivotally connected to the first support section and a second arm pivotably connected to the first arm and pivotally connected to the second support section.

Definition 27: The system of Definition 25, wherein the linkage is a flexible and collapsible length selected from a group of lengths consisting of: a rope, a cord, a cable, a chain, and a flexible band.

Definition 28: The system of Definition 25, wherein the linkage is extendable.

Definition 29: The system of Definition 17 further comprising at least one center table connected to at least one of the first support section and the second support section and movable between a deployed position when the first support section and the second support section are in the extended state and an undeployed position when the first support section and the second support section are in the compact state, the at least one center table section configured to horizontally extend between the first support section and the second support section in the deployed position.

Definition 30: The system of Definition 17 further comprising an extension table section connected to one of the first support section and the second support section and movable between a deployed position and an undeployed position.

Definition 31: The system of Definition 17 further comprising a first link and a second link connecting the first support section and the second support section, the first link, the second link, the first support section and the second support section arranged to form a four bar linkage.

Definition 32: The system of Definition 17 further comprising:
a first extendable linkage extending between and connected to the first support section and the second support section; and
a second extendable linkage extending between and connected to the first support section and the second support section.

Although the present disclosure has been described with reference to example implementations, workers skilled in the art will recognize that changes may be made in form and detail without departing from the scope of the claimed subject matter. For example, although different example implementations may have been described as including features providing benefits, it is contemplated that the described features may be interchanged with one another or alternatively be combined with one another in the described example implementations or in other alternative implementations. Because the technology of the present disclosure is relatively complex, not all changes in the technology are foreseeable. The present disclosure described with reference to the example implementations and set forth in the following claims is manifestly intended to be as broad as possible. For example, unless specifically otherwise noted, the claims reciting a single particular element also encompass a plurality of such particular elements. The terms “first”, “second”, “third” and so on in the claims merely distinguish different elements and, unless otherwise stated, are not to be specifically associated with a particular order or particular numbering of elements in the disclosure.

What is claimed is:

1. An adjustable content creation system comprising:
a first support section comprising at least one first foot;
a camera mount supported by the first support section; and
a second support section comprising at least one second foot, the second support section being movably coupled to the first section for horizontal movement between a compact state and an extended state.

2. The system of claim 1, wherein the second support section comprises a screen mount for securing a screen in a vertical plane .

3. The system of claim 2 further comprising the screen secured to the second support section.

4. The system of claim 3 further comprising a camera supported by the camera mount and facing the screen.

5. The system of claim 1, wherein the first support section comprises a first table surface, wherein the second support section comprises a second table surface, and wherein edges of the first table surface and the second table surface are in abutment in response to the first support section and the second support section in the compact state.

6. The system of claim 1 further comprising a camera supported by the camera mount.

7. The system of claim 6 further comprising at least one monitor supported by the first support section.

8. The system of claim 7, wherein the first support section has a first longitudinal axis, wherein the second support section has a second longitudinal axis, the first longitudinal axis and the second longitudinal axis extending parallel to one another when the first support section and the second support section are in the compact state and wherein the at least one monitor is pivotable between a first position in which the at least one monitor has a monitor face extending in first a plane parallel to the first longitudinal axis and a second position in which the monitor face extends in a second plane nonparallel to the first longitudinal axis.

9. The system of claim 8, wherein the camera is pivotable between a first camera position facing in a direction perpendicular to the first longitudinal axis and a second camera position facing in a direction non-perpendicular to the first longitudinal axis.

10. The system of claim 1, wherein the first support section comprises at least one first vertical telescopic leg and wherein the second support section comprises at least one second vertical telescopic leg.

11. The system of claim 10, further comprising at least one powered actuator operably coupled to at least one of the at least one first vertical telescopic leg and the at least one second vertical telescopic leg for raising and lowering the first support section and the second support section.

12. The system of claim 11 further comprising a controller configured to output signals to the at least one powered actuator for raising and lowering the first support section and the second support section.

13. The system of claim 1, wherein the first support section comprises a first longitudinal end portion and a second longitudinal end portion, wherein the second support section comprises a first longitudinal end portion and a second longitudinal end portion, wherein the first longitudinal end portion of the first support section is pivotably coupled to the first longitudinal end portion of the second support section, wherein the second longitudinal end portion of the first support section and the second longitudinal end portion of the second support section are free ends connected by a linkage extending therebetween.

14. The system of claim 13, wherein the linkage is a folding linkage comprising a first arm pivotally connected to the first support section and a second arm pivotably connected to the first arm and pivotally connected to the second support section.

15. The system of claim 13, wherein the linkage is a flexible and collapsible length selected from a group of lengths consisting of: a rope, a cord, a cable, a chain, and a flexible band.

16. The system of claim 13, wherein the linkage is extendable.

17. The system of claim 1 further comprising at least one center table section connected to at least one of the first support section and the second support section and movable between a deployed position when the first support section and the second support section are in the extended state and an undeployed position when the first support section and the second support section are in the compact state, the at least one center table section configured to horizontally extend between the first support section and the second support section in the deployed position.

18. The system of claim 1 further comprising an extension table section connected to one of the first support section and the second support section and movable between a deployed position and an undeployed position.

19. The system of claim 1 further comprising a first link and a second link connecting the first support section and the second support section, the first link, the second link, the first support section and the second support section arranged to form a four bar linkage.

20. The system of claim 1 further comprising:
a first extendable linkage extending between and connected to the first support section and the second support section; and
a second extendable linkage extending between and connected to the first support section and the second support section.
